(19) United States
(12) Patent Application Publication
(10) Pub. No.: US 2022/0230959 A1
(43) Pub. Date: Jul. 21, 2022

(54) SEMICONDUCTOR STRUCTURE, METHOD FOR FORMING SEMICONDUCTOR STRUCTURE, AND FUSE ARRAY

(71) Applicant: CHANGXIN MEMORY TECHNOLOGIES, INC., Hefei City, Anhui Province (CN)

(72) Inventors: Mengmeng WANG, Hefei (CN); Jialong LI, Hefei (CN)

(73) Assignee: CHANGXIN MEMORY TECHNOLOGIES, INC., Hefei City, Anhui Province (CN)

(21) Appl. No.: 17/439,960

(22) PCT Filed: Mar. 10, 2021
(86) PCT No.: PCT/CN2021/079976

§ 371 Date: Sep. 16, 2021

(30) Foreign Application Priority Data
Mar. 13, 2020 (CN) 202010174301.1

(51) Int. Cl. H01L 23/525; H01L 23/60; H01L 23/528; H01L 23/532; H01L 23/522

(52) U.S. Cl. CPC H01L 23/5258; H01L 23/60; H01L 23/5283; G11C 29/785; H01L 23/53238; H01L 23/53266; H01L 23/5226; H01L 23/53223

(57) ABSTRACT

The present application relates to a semiconductor structure, a method for forming the semiconductor structure, and a fuse array. The semiconductor structure includes at least two first through holes located above a substrate, a first conductive layer located above and electrically connected with the first through holes, at least two second through holes located above the first conductive layer, and a second conductive layer located above the second through holes and electrically connected with the first conductive layer through the second through holes, wherein projections of the first through holes and the second conductive layer on the substrate are non-overlapping. The semiconductor structure requires relatively low fusing energy.

### CROSS-REFERENCE TO RELATED APPLICATIONS

The present application is a national phase entry of International Patent Application No. PCT/CN2021/079976, filed on Mar. 10, 2021, which claims priority to Chinese Patent Application No. 202010174301.1, filed on Mar. 13, 2020. The aforementioned patent applications are herein incorporated by reference in their entirety.

### TECHNICAL FIELD

The present application relates to the field of semiconductor technologies, and in particular to a semiconductor structure, a method for forming the semiconductor structure, and a fuse array.

### BACKGROUND

With the improvement of the level of semiconductor technologies and the increase in the complexity of integrated circuits, the number of devices in a chip increases continuously, and a failure of an individual component such as a transistor or a memory cell often disables the whole integrated circuit.

For example, a DRAM chip manufactured by the semiconductor technologies will inevitably produce a defective memory cell, while a redundant memory cell is usually formed on the DRAM chip. The DRAM chip can be repaired by permanently replacing the defective memory cell with the redundant memory cell, and a common method is to form some fusible connecting wires, i.e., fuse structures, in the integrated circuit. Upon completion of the production of the chip, if some of the memory cells or circuits have functional problems, the fuse structures relevant to the defective circuits can be selectively fused (or broken), and meanwhile, the redundant memory cell is activated to form new circuits for replacement, so as to achieve the purpose of repairing.

A laser fuse is a commonly used fuse structure, which is fused by a laser beam to make the circuit structure change. A laser fuse structure in the prior art requires a large amount of energy for the subsequent fuse blowing process, resulting in difficult control of process parameters and damages caused by excessive energy to devices around the fuse structure.

How to reduce the fuse blowing energy is an urgent problem to be solved at present.

### SUMMARY

The present application provides a semiconductor structure, a method for forming the semiconductor structure, and a fuse array, which are capable of reducing laser energy required for fusing.

To solve this problem, the present application provides a semiconductor structure, including at least two first through holes located above a substrate, a first conductive layer located above and electrically connected with the first through holes, at least two second through holes located above the first conductive layer, and a second conductive layer located above the second through holes and electrically connected with the first conductive layer through the second through holes, in which projections of the first through holes and the second conductive layer on the substrate are non-overlapping.

According to the technical solutions of the present application, a method for forming a semiconductor structure is further provided. The method includes: forming at least two first through holes above the substrate; forming a first conductive layer above the first through holes, in which the first conductive layer is electrically connected with the first through holes; forming at least two second through holes above the first conductive layer; and forming a second conductive layer above the second through holes, in which the second conductive layer is electrically connected with the first conductive layer through the second through holes, and projections of the first through holes and the second conductive layer on the substrate are non-overlapping.

In the semiconductor structure provided by the present application, the projections of the first through holes and the second semiconductor layer on the substrate are non-overlapping, and when the second semiconductor layer is fused, the only requirement is to fuse the second semiconductor layer and the second through hole below the second semiconductor layer, which can reduce the fusing energy and make the fusing process easier to control.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIGS. 1A to 1C are schematic structural diagrams of a semiconductor structure according to an embodiment of the present application;

FIGS. 2A to 2C are schematic structural diagrams of a semiconductor structure according to an embodiment of the present application;

FIGS. 3A to 6B are schematic structural diagrams of formation of a semiconductor structure according to an embodiment of the present application;

FIG. 7 is a schematic structural diagram of a fuse array according to an embodiment of the present application; and

FIG. 8 is a schematic top view of a fuse array with a fuse window area formed above according to an embodiment of the present application.

### DESCRIPTION OF EMBODIMENTS

As described in the BACKGROUND section, an existing fuse blowing process requires a large amount of energy. During laser fusing of a fuse, if only the fuse is blown, metal splashing generated during the fusing or metal diffusion and migration caused by a high temperature may still cause a short circuit between two conductive paths connected by the fuse. Especially, in an existing integrated circuit technology, porous dielectric materials are more and more frequently used as materials of dielectric layers between metal layers. In order to completely disconnect the two conductive paths connected by the laser fuse, it is usually necessary to fuse the entire conductive paths vertically, and to perform laser fusing on the fuse and metals on the conductive paths below, such that the metals are completely vaporized and discharged at the high temperature.

To solve the above problem, the inventor proposed a novel semiconductor structure, a method for forming the novel semiconductor structure, and a formed fuse array.

To make objectives, technical means and effects of the present application clearer and more definite, the present application will be further described in detail below with reference to the accompanying drawings. It should be understood that the embodiments described herein are part rather than all of the embodiments of the present application, and are not intended to limit the present application. All other embodiments acquired by those skilled in the art based on the embodiments of the present application without creative work shall fall within the scope of protection of the present application.

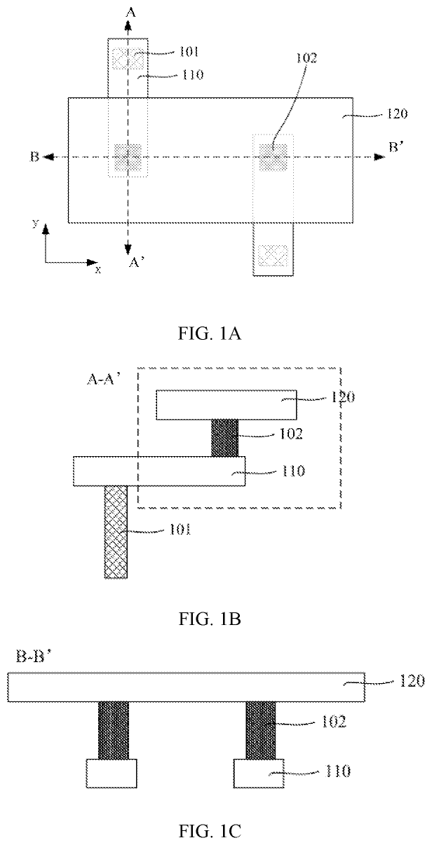

Referring to FIGS. 1A to 1C, which are schematic structural diagrams of a semiconductor structure according to an embodiment of the present application. FIG. 1B is a schematic sectional view along line A-A′ in FIG. 1A, and FIG. 1C is a schematic sectional view along line B-B′ in FIG. 1A.

The semiconductor structure includes: at least two first through holes 101 located above a substrate, a first conductive layer 110 located above and electrically connected with the first through holes 101, at least two second through holes 102 located above the first conductive layer 110, and a second conductive layer 120 located above the second through holes 102 and electrically connected with the first conductive layer 110 through the second through holes 102, wherein projections of the first through holes 101 and the second conductive layer 120 on the substrate are non-overlapping.

The first through holes 101, the second through holes 102, the first conductive layer 110, and the second conductive layer 120 are all formed in a dielectric layer (not shown in the figures).

In this embodiment, two first through holes 101 are taken as an example. The first conductive layer 110 is an inverted metal block. In this embodiment, two first conductive layers 110 are taken as an example. The first conductive layers 110, the first through holes 101 below and the second through holes 102 above constitute a conductive path. In this embodiment, the two first through holes 101 and the two first conductive layers 110 form two conductive paths, and the second conductive layer 120 is connected to the two conductive paths through the second through holes 102, such that the two conductive paths are electrically connected.

In this embodiment, the second conductive layer 120 is a second metal layer, and the first conductive layer 110 is a first metal layer. Correspondingly, the first through hole 101 is a contact hole connected to the substrate or a transistor, and the second through hole 102 is a connection through hole between metal layers.

In other embodiments, the second conductive layer 120 may also be one of an N^{th} metal layer, an (N−1)^{th} metal layer, and an (N−2)^{th} metal layer, and N is a positive integer greater than or equal to 5; and the first conductive layer 110 is the next metal layer in the second conductive layer 120. Other metal layers are formed below the first conductive layer 110. The second through hole 102 is a connection through hole between the metal layers, and the first through hole 101 is also a connection through hole between the metal layers.

The first conductive layer 110 is made of one or more of polysilicon, tungsten metal, aluminum metal, and copper metal, and the second conductive layer 120 is made of one or more of tungsten metal, aluminum metal, and copper metal. The first conductive layer 110 and the second conductive layer 120 may be made of the same or different materials. Those skilled in the art can select appropriate conductive materials according to actual locations of the first conductive layer 110 and the second conductive layer 120. Since the second conductive layer 120 is located above and is relatively long, it is necessary to select a material with smaller resistivity so as to reduce the resistance. In one embodiment, the first conductive layer 110 is made of aluminum, and the second conductive layer 120 is made of copper. In other embodiments, both the first conductive layer 110 and the second conductive layer 120 are made of copper.

Suitable materials of the through holes may be selected according to the locations of the first through hole 101 and the second through hole 102. In one embodiment, the first through hole 101 is a contact through hole connected to a transistor and is made of tungsten, and the second through hole 102 is a connection through hole between metal layers and is made of copper. In another embodiment, the first through hole 101 and the second through hole 102 are made of the same material, i.e., copper or other metals.

The projections of the first through hole 101 and the second conductive layer 120 on the substrate are non-overlapping, and the projection of the first through hole 101 is located outside the projection of the second conductive layer 120. For these reasons, in the process of fusing the second conductive layer 120, after the second conductive layer 120 and the second through hole 102 directly under the second conductive layer, as well as part of the first conductive layer 110, are fused, the fused metal material is kept a relatively long distance away from the first through hole 101, and thus it is difficult to cause a short circuit between the fused metal material and the first through hole 101. Therefore, when the second conductive layer 120 is fused, the only requirement is to fuse the second conductive layer 120 and the second through hole 102 within a projection plane of the second conductive layer 120. Further, the part of the first conductive layer 110 below the second through hole 102 may be fused, i.e., only a conductive structure in the dashed box of FIG. 1B needs to be fused to ensure that the conductive paths may be completely disconnected. There is no need to fuse all the conductive material on the entire conductive path below, thus avoiding use of excessive laser energy during fusing and further avoiding damages to devices around a fuse structure. A horizontal distance between the first through hole 101 and the second conductive layer 120 may be reasonably designed according to layout space, etc. The horizontal distance may be 0.5 μm to 10 μm, but in consideration of different manufacturers and different manufacturing processes, a specific value of the horizontal distance should not be understood as a limitation to the semiconductor structure of the present application. Reasonable adjustment can be made by those skilled in the art on this basis.

Further, when the first conductive layer is a second metal layer or an upper metal layer, projections of conductive layers on the conductive paths connected below the first through hole 101 and of the through holes between the layers on the substrate are non-overlapping, such that the conductive through holes are always located outside the projections of the conductive layers connected above, thereby avoiding a short circuit between the conductive layers below the first through hole or the connection through hole and the second conductive layer during fusing of the second conductive layer.

In this embodiment, the second conductive layer 120 is arranged along a direction x, and the first conductive layer 110 is arranged along a direction y, i.e., a length direction of the second conductive layer 120 is the direction x, and a length direction of the first conductive layer 110 is the direction y. The direction x is perpendicular to the direction y to maximize a distance between the first through hole 101 and the second conductive layer 120 as much as possible. In this embodiment, the projections of the two first through holes 110 on the substrate are respectively located at two sides of the projection of the second conductive layer 120 on the substrate, which increases the distance between the two conductive paths in which the two first through holes 110 are formed and avoids the problem of short circuit caused by splashing or diffusion of fused metals between the two conductive paths during fusing of the second conductive layer 120.

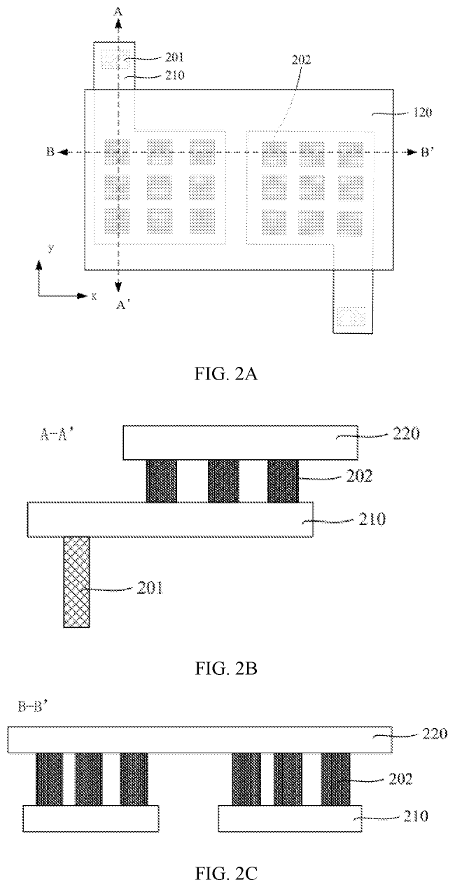

Referring to FIGS. 2A to 2C, which are schematic structural diagrams of a semiconductor structure according to another embodiment of the present application. FIG. 2B is a schematic sectional view along line A-A′ in FIG. 2A, and FIG. 2C is a schematic sectional view along line B-B′ in FIG. 2A.

In this embodiment, the second conductive layer 220 is connected to each first conductive layer 210 through a plurality of second through holes 202, and correspondingly, an overlapping area between the first conductive layer 210 and the second conductive layer 220 is larger, which is beneficial to fuse the first conductive layer 210 below the projection of the second conductive layer 220 when the second conductive layer 220 is fused, so as to reduce the difficulty in aligning laser beams during laser fusing.

In other embodiments of the present application, the semiconductor structure further includes a protective layer and the fuse window area. The protective layer covers the conductive layer, and the fuse window area is located above the protective layer. Both the second through hole and the second conductive layer are located in the fuse window area. When the second conductive layer does not need to be fused, the protective layer is capable of protecting the second conductive layer, and when the second conductive layer needs to be fused, the second conductive layer and the second through holes below, as well as part of the first conductive layer, are directly fused through the fuse window area.

Further, the fuse window area is a groove of which a bottom is part of the protective layer.

According to the technical solutions of the present application, a method for forming the above-mentioned semiconductor structure is further provided.

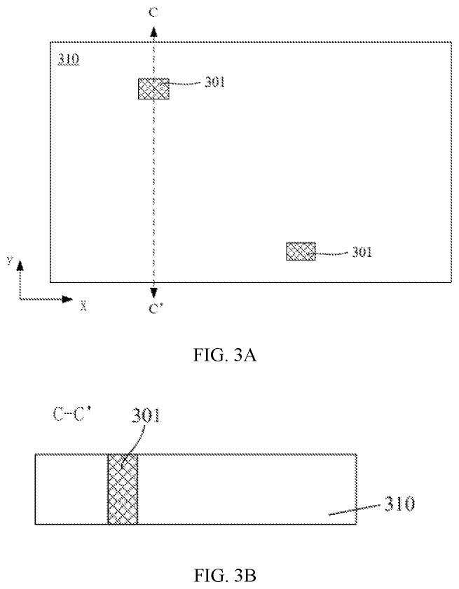

Referring to FIGS. 3A to 6B, which show a method for forming a semiconductor structure according to an embodiment of the present application.

Referring to FIGS. 3A to 3B, a substrate (not shown in the figures) is provided, a first dielectric layer 310 with at least two first through holes 301 formed therein is formed on the substrate. FIG. 3B is a schematic sectional view along line C-C′ in FIG. 3A.

A method for forming the first through holes 301 includes: etching the first dielectric layer 310 to a lower-layer conductor to form through holes, filling the through holes with a conductive material, and performing planarization to form the first through holes 301. In this embodiment, formation of the two first through holes 301 is taken as an example.

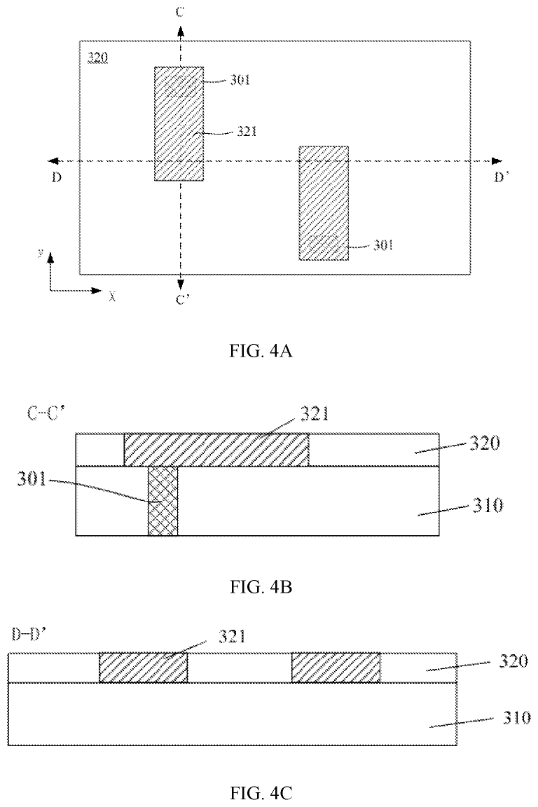

Referring to FIGS. 4A to 4C, a second dielectric layer 320 and a first conductive layer 321 located in the second dielectric layer 320 are formed on the first dielectric layer 310, and the first conductive layer 321 is connected to the first through holes 301. FIG. 4B is a schematic sectional view along line C-C′ in FIG. 4A, and FIG. 4C is a schematic sectional view along line D-D′ in FIG. 4A.

A method for forming the first conductive layer 321 includes etching the second dielectric layer 320 to form a groove, and then filling the groove with a conductive material to form the first conductive layer 321. In other embodiments, the first conductive layer 321 may also be formed by forming and then patterning a conductive material layer that covers the first dielectric layer 310. After that, a dielectric material is formed on the first conductive layer 321, and planarized to form a second dielectric layer 320 of which a surface is flush with a surface of the first conductive layer 321. The first conductive layer 321 may have a cross section in the shape of a plane figure, such as a rectangle, a circle or a polygon.

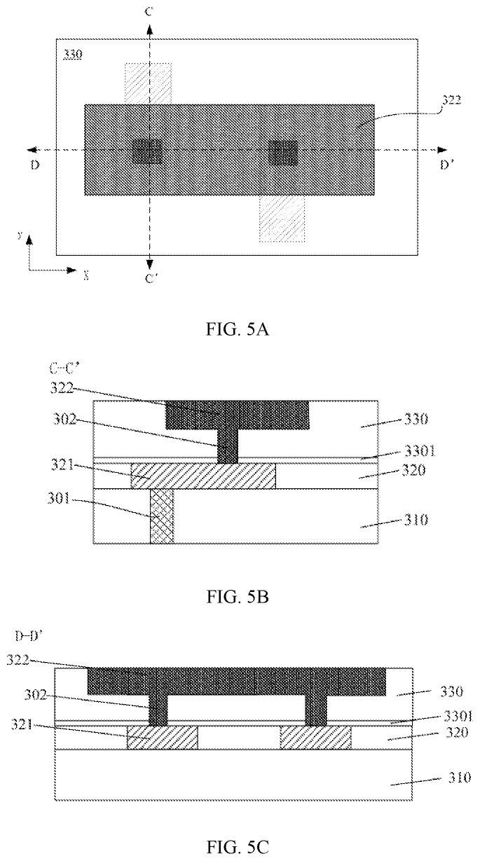

Referring to FIGS. 5A to 5C, a barrier layer 3301 and a third dielectric layer 330 covering the barrier layer 3301 are formed on the surface of the second dielectric layer 320; and a second through hole 302 and a second conductive layer 322 located in the second through hole 302 are formed in the third dielectric layer 330. FIG. 5B is a schematic sectional view along line C-C′ in FIG. 5A, and FIG. 5C is a schematic sectional view along line D-D′ in FIG. 5A.

A bottom of the second through hole 302 penetrates the barrier layer 3301, is located on the surface of the first conductive layer 321 and connects the first conductive layer 321 to the second conductive layer 322, and the second conductive layer 322 connects the two first conductive layers 321 through the second through hole 302, such that the two conductive paths where the two first conductive layers 321 are located are connected to each other. The two conductive paths may be disconnected by fusing the second conductive layer 322 with laser.

The second conductive layer 322 and the second through hole 302 may be formed by the Dual Damascene process. Specifically, a through hole and a groove located above the through hole are formed in the third dielectric layer 330, and then filled with a conductive material, and planarization is performed to form the second through hole 302 in the through hole and the second conductive layer 322 in the groove.

In other embodiments, the second through hole 302 and the second conductive layer 322 may also be formed separately.

A metal barrier layer may also be formed between the second conductive layer 322 and the third dielectric layer 330, as well as the second through hole 302 and the third dielectric layer 330, to avoid diffusion of atoms in the metal material. The metal barrier layer may be made from one of TiN, TaN, etc.

In some embodiments, the barrier layer 3301 may be made from SiN, SiON, SiCN, etc., to prevent metal atoms in the first conductive layer 321 from diffusion into the third dielectric layer 330. The first dielectric layer 310, the second dielectric layer 320 and the third dielectric layer 330 may be made from materials of interlayer dielectric layers commonly used for support of integrated circuits, such as silicon oxide, silicon oxynitride and silicon oxycarbide, or low-K dielectric materials such as amorphous carbon and porous silicon oxide.

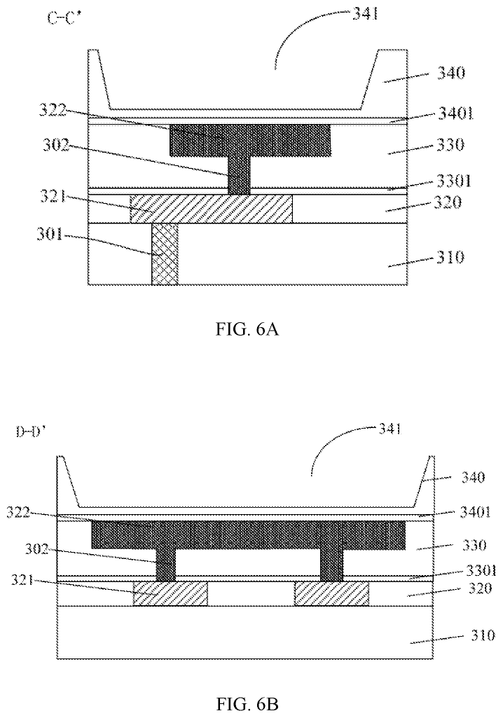

Referring to FIGS. 6A to 6B, a barrier layer 3401 covering the third dielectric layer 330 and a fourth dielectric layer 340 located on a surface of the barrier layer 3401 are sequentially formed; and the fourth dielectric layer 340 is etched to form a fuse window area 341 located above the second conductive layer 322 and the second through hole 302.

The fuse window area 341 is located above the semiconductor structure, and is usually larger than the semiconductor structure in size, such that the semiconductor structure is located in the area where the fuse window area 341 is located. A dielectric material of partial thickness is provided between a bottom of the fuse window area 341 and a surface of the second conductive layer 322 as a protective layer covering the second conductive layer 322. When the second conductive layer 322 does not need to be fused, the protective layer is capable of protecting the second conductive layer 322, and when the second conductive layer 322 needs to be fused, the second conductive layer 322 and the second through hole 302 are directly fused through the fuse window area 341.

The thickness of the protective layer on the surface of the second conductive layer 322 is relatively small to further reduce energy during laser fusing. In some embodiments, an alignment mark may be further formed in a metal layer where the second conductive layer is located or an upper metal layer, and the alignment mark is located outside the fuse window area 341. All fuse structures have fixed coordinates relative to the alignment mark, which helps to perform laser alignment on the fuse structures by the alignment mark.

In this embodiment, the protective layer includes a barrier layer 3401 and a dielectric layer of partial thickness remaining on the barrier layer 3401 after the fourth dielectric layer 340 is etched.

In other embodiments, in the process of forming the fuse window area 341, the barrier layer 3401 may be used as an etching stop layer, such that only the barrier layer 3401 covers the second conductive layer 322 as a protective layer. When the barrier layer 3401 is used as the etching stop layer, it is easier to control the time at which the etching of the fourth dielectric layer 340 stops, and the thickness of the protective layer is only determined by the thickness of the barrier layer 3401. The barrier layer 3401 and the fourth dielectric layer 340 may be selectively made from two different materials, such that during the etching of the fourth dielectric layer 340, a relatively high etching selection ratio is provided for the fourth dielectric layer 340 and the barrier layer 3401. The barrier layer 3401 is further configured to prevent the material of the second conductive layer 322 from diffusion into the fourth dielectric layer 340. In some embodiments, the barrier layer 3401 may be made from silicon nitride, silicon carbon nitride, etc., and the fourth dielectric layer 340 may be made from materials of interlayer dielectric layers commonly used for support of integrated circuits, such as silicon oxide, silicon oxynitride and silicon oxycarbide, or low-K dielectric materials such as amorphous carbon and porous silicon oxide.

In the above embodiments, the first dielectric layer 310, the second dielectric layer 320, the third dielectric layer 330, the fourth dielectric layer 340, and the barrier layers 3301 and 3401 all serve as interlayer dielectric layers above the substrate or part of the interlayer dielectric layers for isolating the metal layers and interlayer interconnection structures.

According to the embodiments of the present application, a fuse array is further provided. The fuse array includes the semiconductor structure formed in the above embodiments. Specifically, the plurality of semiconductor structures is arranged in an array of M rows by N columns. In some embodiments, both M and N are positive even numbers. The fuse array constitutes a programmable array, and fusing control of a circuit is performed by fusing selection of each semiconductor structure in the fuse array.

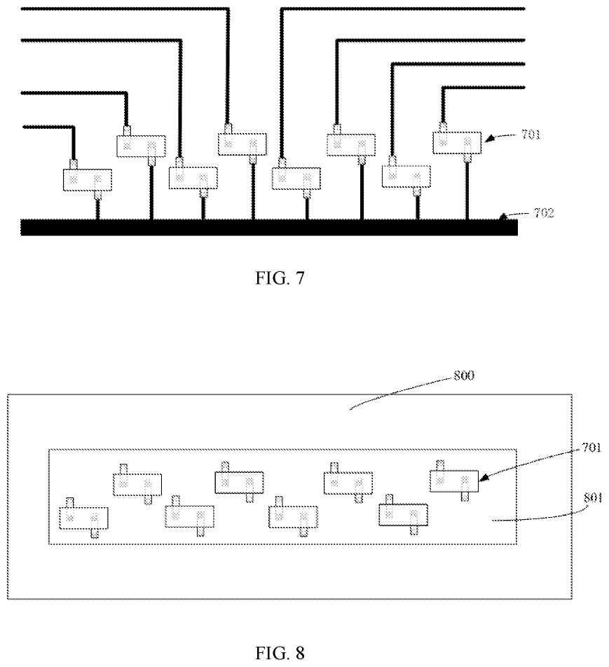

Referring to FIG. 7, which is a schematic structural diagram of a fuse array according to an embodiment of the present application.

In this embodiment, the fuse array includes eight semiconductor structures 701 described above, which are arranged in an array of 2 rows by 4 columns.

In order to reduce the area of the fuse array, semiconductors in different rows are staggered to reduce spacing between the adjacent rows.

The first through holes of the semiconductor structure are connected to an underlying circuit 702, and the circuit 702 may be connected to other semiconductor devices. By selectively fusing some of the semiconductor structures, a connection relationship of the circuit 702 may be changed, so that operations, e.g., repair, of a chip may be realized. For example, a defective memory cell is replaced with a redundant memory cells to repair the memory chip.

Referring to FIG. 8, which is a schematic top view of a fuse window area formed above a fuse array according to an embodiment of the present application.

A dielectric layer 800 with a fuse window area 801 formed therein is formed above the fuse array. The fuse window area 801 is located above the fuse array and exposes all fuse structures in the fuse array, i.e., the semiconductor structures 701. The dielectric layer 800 of partial thickness may be provided between a bottom of the fuse window area 801 and the semiconductor structures 701 as a protective layer.

The above descriptions are merely embodiments of the present application. It should be noted that some improvements and modifications can also be made by those of ordinary skill in the art without departing from the principles of the present application, and these improvements and modifications shall all be construed as falling within the scope of protection of the present application.

What is claimed is:

1. A semiconductor structure, comprising:
at least two first through holes located above a substrate;
a first conductive layer located above and electrically connected with the first through holes;
at least two second through holes located above the first conductive layer; and
a second conductive layer located above the second through holes and electrically connected with the first conductive layer through the second through holes,
wherein projections of the first through holes and the second conductive layer on the substrate are non-overlapping.

2. The semiconductor structure according to claim 1, further comprising:
a protective layer covering the second conductive layer; and
a fuse window area located above the protective layer, wherein both the second through holes and the second conductive layer are located in the fuse window area.

3. The semiconductor structure according to claim 2, wherein the fuse window area is a groove of which a bottom is part of the protective layer.

4. The semiconductor structure according to claim 3, wherein the second conductive layer is arranged in a direction x, the first conductive layer is arranged in a direction y, and the direction x is perpendicular to the direction y.

5. The semiconductor structure according to claim 1, wherein the first through hole comprises one of: a contact hole and a through hole between metal layers.

6. The semiconductor structure according to claim 1, wherein the second conductive layer comprises one of an N^{th} metal layer, an (N−1)^{th} metal layer, an (N−2)^{th} metal layer and a second metal layer, and N is a positive integer greater than or equal to 5.

7. The semiconductor structure according to claim 1, wherein the first conductive layer and the second conductive layer have different electric conductivity.

8. The semiconductor structure according to claim 7, wherein the first conductive layer is made of one or more of polysilicon, tungsten metal, aluminum metal, and copper metal, and the second conductive layer is made of one or more of tungsten metal, aluminum metal, and copper metal.

9. A fuse array, comprising the semiconductor structure of claim 1, wherein the plurality of semiconductor structures is arranged in an array of M rows by N columns, and both M and N are positive even numbers.

10. A method for forming a semiconductor structure, comprising:
forming at least two first through holes above the substrate;
forming a first conductive layer above the first through holes, wherein the first conductive layer is electrically connected with the first through holes;
forming at least two second through holes above the first conductive layer; and
forming a second conductive layer above the second through holes, wherein the second conductive layer is electrically connected with the first conductive layer through the second through holes,
wherein projections of the first through holes and the second conductive layer on the substrate are non-overlapping.

11. The method for forming the semiconductor structure according to claim 10, further comprising:
forming a protective layer above the second conductive layer; and
forming a groove above the protective layer as a fuse window area, wherein both the second through holes and the second conductive layer are located in the fuse window area.
